(19) United States
(12) Patent Application Publication
(10) Pub. No.: US 2026/0214793 A1
(43) Pub. Date: Jul. 23, 2026

(54) HYBRID CIRCUIT BOARD

(71) Applicant: TONG HSING ELECTRONIC INDUSTRIES, LTD., Taoyuan City (TW)

(72) Inventors: YI-YUAN LIN, Taoyuan City (TW); DEI-CHENG LIU, Taipei City (TW); SHIH-HAN WU, Taipei City (TW); JIAN-YU SHIH, Taoyuan City (TW)

(21) Appl. No.: 19/372,212

(22) Filed: Oct. 28, 2025

Related U.S. Application Data
(60) Provisional application No. 63/748,821, filed on Jan. 23, 2025.

(30) Foreign Application Priority Data
Jul. 9, 2025 (TW) 114125893
Oct. 7, 2025 (TW) 114138493

(51) Int. Cl. H05K 1/03; H05K 1/02; H05K 1/11; H05K 1/18

(52) U.S. Cl. CPC H05K 1/0306; H05K 1/0201; H05K 1/0271; H05K 1/0313; H05K 1/116; H05K 1/188; H05K 2201/09154; H05K 2201/09481; H05K 2201/09536; H05K 2201/096; H05K 2201/09618

(57) ABSTRACT

A hybrid circuit board includes a ceramic core layer and two stacked layers respectively formed on two opposite sides of the ceramic core layer. The ceramic core layer includes a ceramic substrate and a connection circuit. The ceramic substrate has a thru-hole, and the connection circuit has an embedded segment embedded fully in the thru-hole and two connection segments that are respectively connected to two opposite ends of the embedded segment. Each of the two stacked layers includes a dielectric layer formed on the ceramic substrate and a circuit that is embedded in the dielectric layer. In each of the two stacked layers, one end of the circuit is connected to one of the two connection segments, and another end of the circuit is exposed from the dielectric layer. The circuits of the two stacked layers are electrically coupled to each other through the connection circuit.

### CROSS-REFERENCE TO RELATED PATENT APPLICATION

This application claims the benefit of priority to Taiwan Patent Application No. 114125893, filed on Jul. 9, 2025. The entire content of the above identified application is incorporated herein by reference.

This application claims the benefit of priority to the U.S. Provisional Patent Application Ser. No. 63/748,821, filed on Jan. 23, 2025, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a hybrid circuit board.

### BACKGROUND OF THE DISCLOSURE

A conventional hybrid circuit board uses a silicon substrate or a glass substrate as a core layer, such that a heat dissipation property and an anti-bending property of the conventional hybrid circuit board are limited by the silicon substrate and the glass substrate and are difficult to be improved.

### SUMMARY OF THE DISCLOSURE

In response to the above-referenced technical inadequacies, the present disclosure provides a hybrid circuit board for effectively improving on the issues associated with conventional hybrid circuit boards.

In order to solve the above-mentioned problems, one of the technical aspects adopted by the present disclosure is to provide a hybrid circuit board, which includes a ceramic core layer, a first stacked layer, and a second stacked layer. The ceramic core layer includes a ceramic substrate and a connection circuit. The ceramic substrate has a first surface, a second surface being opposite to the first surface, and a thru-hole that penetrates from the first surface to the second surface. The connection circuit has an embedded segment filled fully in the thru-hole, a first connection segment, and a second connection segment. The first connection segment and the second connection segment are respectively connected to two opposite ends of the embedded segment, and are respectively formed on the first surface and the second surface. The first stacked layer is formed on the first surface of the ceramic substrate, and the first connection segment is embedded in the first stacked layer. The first stacked layer includes a first organic dielectric layer, a first inorganic dielectric layer, and a first circuit. The first organic dielectric layer and the first inorganic dielectric layer are stacked on the first surface. The first circuit is embedded in the first organic dielectric layer and the first inorganic dielectric layer. One end of the first circuit is connected to the first connection segment, and another end of the first circuit is exposed from one of the first organic dielectric layer and the first inorganic dielectric layer. The second stacked layer is formed on the second surface of the ceramic substrate, and the second connection segment is embedded in the second stacked layer. The second stacked layer includes a second organic dielectric layer, a second inorganic dielectric layer, and a second circuit. The second organic dielectric layer and the second inorganic dielectric layer are stacked on the second surface. The second circuit is embedded in the second organic dielectric layer and the second inorganic dielectric layer. One end of the second circuit is connected to the second connection segment, another end of the second circuit is exposed from one of the second organic dielectric layer and the second inorganic dielectric layer, and the first circuit and the second circuit are electrically coupled to each other through the connection circuit.

In order to solve the above-mentioned problems, another one of the technical aspects adopted by the present disclosure is to provide a hybrid circuit board, which includes a ceramic core layer, a first stacked layer, and a second stacked layer. The ceramic core layer includes a ceramic substrate and a connection circuit. The ceramic substrate has a first surface, a second surface being opposite to the first surface, and a thru-hole that penetrates from the first surface to the second surface. The connection circuit has an embedded segment filled fully in the thru-hole, a first connection segment, and a second connection segment. The first connection segment and the second connection segment are respectively connected to two opposite ends of the embedded segment, and are respectively formed on the first surface and the second surface. The first stacked layer includes a first dielectric layer formed on the first surface and a first circuit that is embedded in the first dielectric layer. One end of the first circuit is connected to the first connection segment, and another end of the first circuit is exposed from the first dielectric layer. The second stacked layer includes a second dielectric layer formed on the second surface and a second circuit that is embedded in the second dielectric layer. One end of the second circuit is connected to the second connection segment, another end of the second circuit is exposed from the second dielectric layer, and the first circuit and the second circuit are electrically coupled to each other through the connection circuit.

Therefore, the hybrid circuit board of the present disclosure is provided with the ceramic core layer to replace the conventional silicon substrate or the conventional glass substrate, and the first stacked layer and the second stacked layer are ensured to be electrically coupled to each other through the ceramic core layer, thereby effectively increasing the heat dissipation property and the anti-bending property of the hybrid circuit board.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a hybrid circuit board according to a first embodiment of the present disclosure;

FIG. 2 is a schematic enlarged view of part II of FIG. 1;

FIG. 3 is a schematic cross-sectional view of the hybrid circuit board according to a second embodiment of the present disclosure;

FIG. 4 is a schematic cross-sectional view of the hybrid circuit board according to a third embodiment of the present disclosure;

FIG. 5 is a schematic enlarged view of part V of FIG. 4;

FIG. 6 is a schematic cross-sectional view of the hybrid circuit board in another configuration according to the third embodiment of the present disclosure;

FIG. 7 is a schematic cross-sectional view of the hybrid circuit board according to a fourth embodiment of the present disclosure;

FIG. 8 is a schematic cross-sectional view of the hybrid circuit board in another configuration according to the fourth embodiment of the present disclosure; and

FIG. 9 is a schematic top view showing a part of FIG. 7 when a first dielectric layer is omitted.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

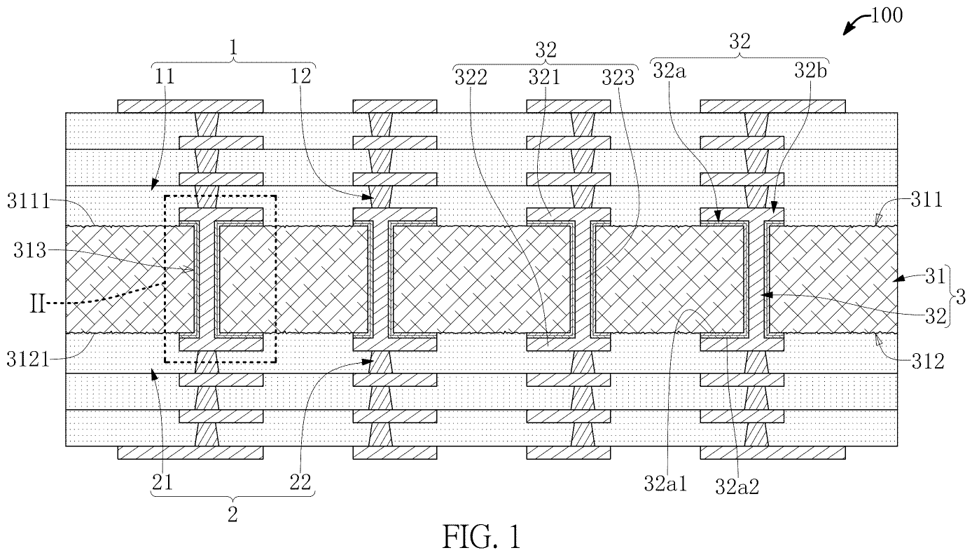

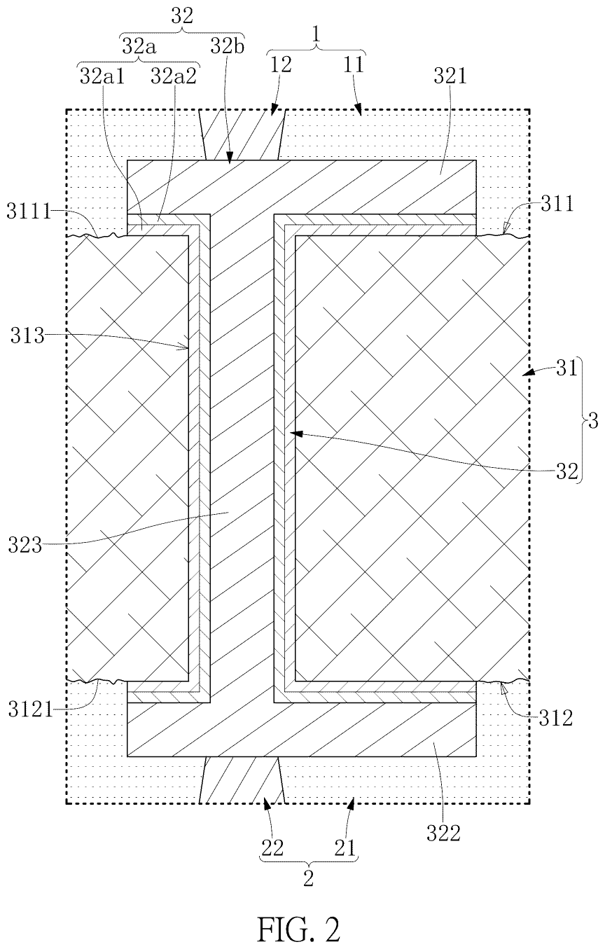

Referring to FIG. 1 and FIG. 2, a first embodiment of the present disclosure is provided. The present embodiment provides a hybrid circuit board 100 including a ceramic core layer 3, a first stacked layer 1, and a second stacked layer 2, the latter two of which are respectively formed on two opposite sides of the ceramic core layer 3. The first stacked layer 1 and the second stacked layer 2 can be electrically coupled to each other through the ceramic core layer 3. In other words, any circuit board not having a ceramic core layer is different from the hybrid circuit board 100 provided by the present embodiment.

In the present embodiment, the ceramic core layer 3 includes a ceramic substrate 31 and a plurality of connection circuits 32 that are formed on the ceramic substrate 31. The ceramic substrate 31 has a first surface 311, a second surface 312 being opposite to the first surface 311, and a plurality of thru-holes 313 that penetrate from the first surface 311 to the second surface 312.

It should be noted that a quantity of the thru-holes 313 of the ceramic substrate 31 and a quantity of the connection circuits 32 shown in the drawings of the present embodiment can each be more than one, but in other embodiments of the present disclosure not shown in the drawings, the quantity of the thru-hole 313 and the quantity of the connection circuit 32 can each be at least one. Moreover, in order to clearly describe the present embodiment, the following description describes the structure of just one of the connection circuits 32 and the corresponding thru-hole 313 for the sake of brevity.

Specifically, the first surface 311 and the second surface 312 of the ceramic substrate 31 in the present embodiment are parallel to each other and are substantially planar, and the thru-hole 313 is recessed from the first surface 311 (or the second surface 312) to penetrate through the ceramic substrate 31 along a thickness direction, but the present disclosure is not limited thereto. For example, in other embodiments of the present disclosure not shown in the drawings, at least one of the first surface 311 and the second surface 312 can be non-planar, and the thru-hole 313 can be formed by drilling the first surface 311 and the second surface 312 to respectively form two holes that are in spatial communication with each other.

Furthermore, in order to improve the bonding strength between the ceramic substrate 31 and any one of the first stacked layer 1 and the second stacked layer 2, the first surface 311 of the ceramic substrate 31 can have a first modification region 3111, and the second surface 312 of the ceramic substrate 31 can have a second modification region 3121. In the present embodiment, an area of the first modification region 3111 and/or an area of the second modification region 3121 can be adjusted or changed according to practical requirements, and the present disclosure is not limited thereto. In addition, a modification manner of the first modification region 3111 and/or the second modification region 3121 can be a physical modification (e.g., roughening or surface coating) or a chemical modification (e.g., changing material molecular structure or surface functional groups) according to practical requirements. For example, the first surface 311 and/or the second surface 312 can be modified by using a laser process or a wet process to form the first modification region 3111 and/or the second modification region 3121, thereby improving the adhesion of the ceramic substrate 31 to the first stacked layer 1 and the second stacked layer 2.

The connection circuit 32 has an embedded segment 323 filled fully in the thru-hole 313, a first connection segment 321, and a second connection segment 322. The first connection segment 321 and the second connection segment 322 are respectively connected to two opposite ends of the embedded segment 323 (respectively exposed from the first surface 311 and the second surface 312), and are respectively formed on the first surface 311 and the second surface 312. In the present embodiment, the first connection segment 321 and the second connection segment 322 are respectively formed on the first surface 311 and the second surface 312 in a direct plated copper (DPC) manner, and the first connection segment 321 and the second connection segment 322 do not cover the first modification region 3111 and the second modification region 3121, but the present disclosure is not limited thereto.

In order to enable the connection circuit 32 to firmly form on and combine with the ceramic substrate 31, the connection circuit 32 can have a multi-layer structure including a seed layer 32a formed on the ceramic substrate 31 and a circuit layer 32b that is formed on the seed layer 32a. In the present embodiment, the seed layer 32a includes a copper alloy layer 32a1 (e.g., a titanium copper layer or a nickel copper layer) formed on the ceramic substrate 31 in a deposition manner and a copper layer 32a2 that is formed on the copper alloy layer 32a1 in a chemical plating manner, and the circuit layer 32b is formed on the copper layer 32a2 in the DPC manner, but the present disclosure is not limited thereto.

The first stacked layer 1 includes a first dielectric layer 11 formed on the first surface 311 and a first circuit 12 that is embedded in the first dielectric layer 11. In the present embodiment, the first dielectric layer 11 can be a multi-layer structure and can be an inorganic dielectric layer or an organic dielectric layer according to practical requirements, but the present disclosure is not limited thereto.

Specifically, the first connection segment 321 is embedded in the first dielectric layer 11, and the first dielectric layer 11 is connected to (or covers) the first modification region 3111, thereby increasing the bonding strength of the first dielectric layer 11 and the ceramic substrate 31.

Moreover, one end of the first circuit 12 is connected to the first connection segment 321, and another end of the first circuit 12 is exposed from the first dielectric layer 11. It should be noted that, in the drawings of the present embodiment, the first circuit 12 is substantially arranged above the corresponding thru-hole 313, but in other embodiments of the present disclosure not shown in the drawings, the first circuit 12 can be staggered relative to the corresponding thru-hole 313 by being connected to an outer portion of the first connection segment 321.

The second stacked layer 2 includes a second dielectric layer 21 formed on the second surface 312 and a second circuit 22 that is embedded in the second dielectric layer 21. In the present embodiment, the second dielectric layer 21 can be a multi-layer structure and can be an inorganic dielectric layer or an organic dielectric layer according to practical requirements, but the present disclosure is not limited thereto.

In addition, when at least one of the first dielectric layer 11 and the second dielectric layer 21 is an organic dielectric layer, the organic dielectric layer can include at least one of polyimide (PI), ajinomoto build-up film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, hybrid polymer-ceramic materials.

Furthermore, when at least one of the first dielectric layer 11 and the second dielectric layer 21 is an inorganic dielectric layer, the inorganic dielectric layer can include at least one of SiO₂, AlON, ZTA, BeO, SiC, Al₂O₃, AlN, Si₃N₄, ZrO_{2,} Quartz, Mica, HfO₂, Ta₂O₃, MgO, TiO₂, and BN.

Specifically, the second connection segment 322 is embedded in the second dielectric layer 21, and the second dielectric layer 21 is connected to (or covers) the second modification region 3121, thereby increasing the bonding strength of the second dielectric layer 21 and the ceramic substrate 31.

Moreover, one end of the second circuit 22 is connected to the second connection segment 322, and another end of the second circuit 22 is exposed from the second dielectric layer 21. It should be noted that, in the drawings of the present embodiment, the second circuit 22 is substantially arranged under the corresponding thru-hole 313, but in other embodiments of the present disclosure not shown in the drawings, the second circuit 22 can be staggered relative to the corresponding thru-hole 313 by being connected to an outer portion of the second connection segment 322.

In summary, the hybrid circuit board 100 of the present embodiment is provided with the ceramic core layer 3 to replace the conventional silicon substrate or the conventional glass substrate, and the first stacked layer 1 and the second stacked layer 2 are ensured to be electrically coupled to each other through the ceramic core layer 3, thereby effectively increasing the heat dissipation property and the anti-bending property of the hybrid circuit board 100.

### Second Embodiment

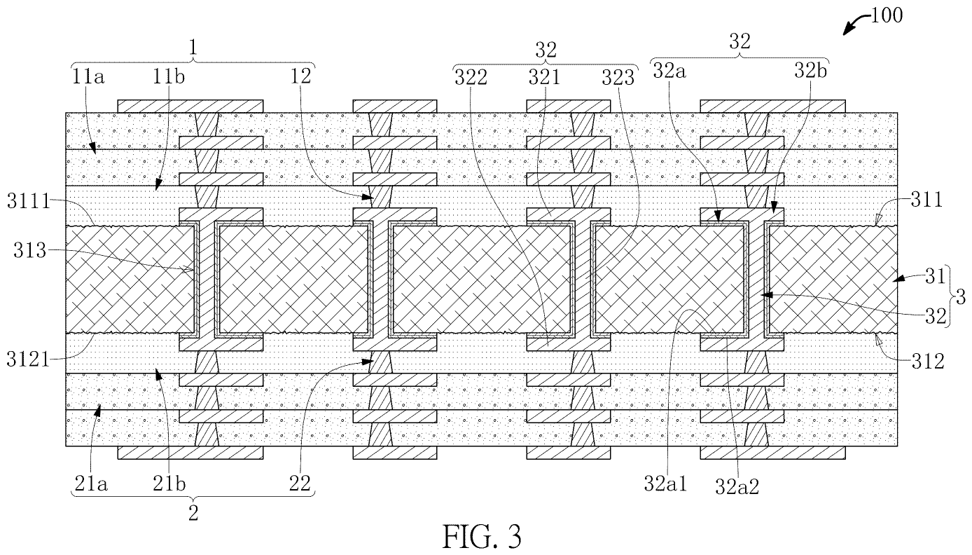

Referring to FIG. 3, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

The present embodiment provides a hybrid circuit board 100 including a ceramic core layer 3, a first stacked layer 1, and a second stacked layer 2, the latter two of which are respectively formed on two opposite sides of the ceramic core layer 3. The first stacked layer 1 and the second stacked layer 2 can be electrically coupled to each other through the ceramic core layer 3. In other words, any circuit board not having a ceramic core layer is different from the hybrid circuit board 100 provided by the present embodiment. It should be noted that the ceramic core layer 3 of the present embodiment is substantially identical to that of the first embodiment, and is not described again for the sake of brevity.

The first stacked layer 1 is formed on the first surface 311 of the ceramic substrate 31, and the first connection segment 321 is embedded in the first stacked layer 1. The first stacked layer 1 includes a first organic dielectric layer 11a, a first inorganic dielectric layer 11b, and a first circuit 12. The first organic dielectric layer 11a and the first inorganic dielectric layer 11b are stacked on the first surface 311, and the first circuit 12 is embedded in the first organic dielectric layer 11a and the first inorganic dielectric layer 11b.

Specifically, the first organic dielectric layer 11a can have a single layer structure or a multi-layer structure, and the first inorganic dielectric layer 11b can be a single layer structure or a multi-layer structure. Moreover, one end of the first circuit 12 is connected to the first connection segment 321, and another end of the first circuit 12 is exposed from one of the first organic dielectric layer 11a and the first inorganic dielectric layer 11b. It should be noted that the first circuit 12 of the present embodiment is substantially identical to that of the first embodiment, and is not described again for the sake of brevity.

In the drawings of the present embodiment, the first inorganic dielectric layer 11b of the first stacked layer 1 is formed on the first surface 311 and is connected to the first modification region 3111, so that the first connection segment 321 is embedded in the first inorganic dielectric layer 11b, and the first organic dielectric layer 11a is stacked on the first inorganic dielectric layer 11b for allowing another end of the first circuit 12 to be exposed therefrom, but the present disclosure is not limited thereto.

For example, in other embodiments of the present disclosure not shown in the drawings, the first organic dielectric layer 11a of the first stacked layer 1 is formed on the first surface 311 and is connected to the first modification region 3111, so that the first connection segment 321 is embedded in the first organic dielectric layer 11a, and the first inorganic dielectric layer 11b is stacked on the first organic dielectric layer 11a for allowing another end of the first circuit 12 to be exposed therefrom.

The second stacked layer 2 is formed on the second surface 312 of the ceramic substrate 31, and the second connection segment 322 is embedded in the second stacked layer 2. The second stacked layer 2 includes a second organic dielectric layer 21a, a second inorganic dielectric layer 21b, and a second circuit 22. The second organic dielectric layer 21a and the second inorganic dielectric layer 21b are stacked on the second surface 312, and the second circuit 22 is embedded in the second organic dielectric layer 21a and the second inorganic dielectric layer 21b.

Specifically, the second organic dielectric layer 21a can have a single layer structure or a multi-layer structure, and the second inorganic dielectric layer 21b can be a single layer structure or a multi-layer structure. Moreover, one end of the second circuit 22 is connected to the second connection segment 322, and another end of the second circuit 22 is exposed from one of the second organic dielectric layer 21a and the second inorganic dielectric layer 21b. It should be noted that the second circuit 22 of the present embodiment is substantially identical to that of the first embodiment, and is not described again for the sake of brevity.

In the drawings of the present embodiment, the second inorganic dielectric layer 21b of the second stacked layer 2 is formed on the second surface 312 and is connected to the second modification region 3121, so that the second connection segment 322 is embedded in the second inorganic dielectric layer 21b, and the second organic dielectric layer 21a is stacked on the second inorganic dielectric layer 21b for allowing another end of the second circuit 22 to be exposed therefrom, but the present disclosure is not limited thereto.

For example, in other embodiments of the present disclosure not shown in the drawings, the second organic dielectric layer 21a of the second stacked layer 2 is formed on the second surface 312 and is connected to the second modification region 3121, so that the second connection segment 322 is embedded in the second organic dielectric layer 21a, and the second inorganic dielectric layer 21b is stacked on the second organic dielectric layer 21a for allowing another end of the second circuit 22 to be exposed therefrom.

Any one of the first organic dielectric layer 11a and the second organic dielectric layer 21a includes at least one of polyimide (PI), ajinomoto build-up film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, and hybrid polymer-ceramic materials.

Any one of the first inorganic dielectric layer 11b and the second inorganic dielectric layer 21b includes at least one of SiO₂, AlON, ZTA, BeO, SiC, Al₂O₃, AlN, Si₃N₄, ZrO_{2,} Quartz, Mica, HfO₂, Ta₂O₃, MgO, TiO₂, and BN.

Moreover, the first inorganic dielectric layer 11b and the second inorganic dielectric layer 21b can be manufactured through a chemical vapor deposition (CVD) manner, a physical vapor deposition (PVD) manner, or an electrophoretic deposition (EPD) manner. It should be noted that, the quartz and the mica are minerals that are extracted from natural ores and then processed or synthesized, so that the quartz and the mica are not formed by deposition manners.

Specifically, the CVD manner in the present embodiment can include an atomic layer deposition manner, a high pressure CVD (HPCVD) manner, a plasma enhanced CVD (PECVD) manner, a microwave plasma CVD (MPCVD) manner, a low pressure CVD (LPCVD), a vapor phase epitaxy (VPE) manner, a metal organic CVD (MOCVD) manner, and/or a spray pyrolysis manner.

Furthermore, the PVD manner in the present embodiment can include an E-Gun Evaporation manner, an ion beam evaporation manner, a DC magnetron sputtering manner, an ion beam sputtering manner, a pulse laser deposition (PLD) manner, a cathodic arc deposition manner, and/or a molecular beam epitaxy (MBE) manner.

### Third Embodiment

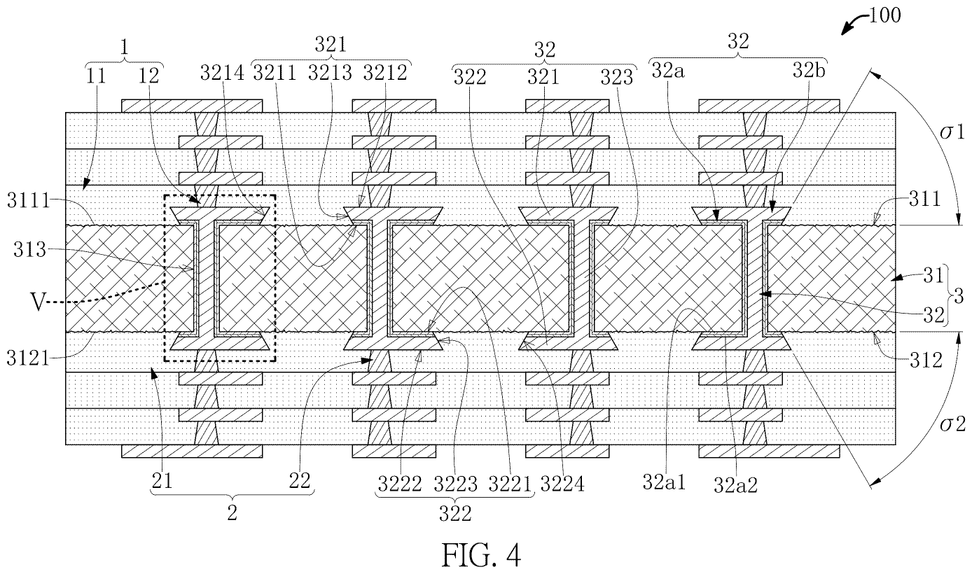

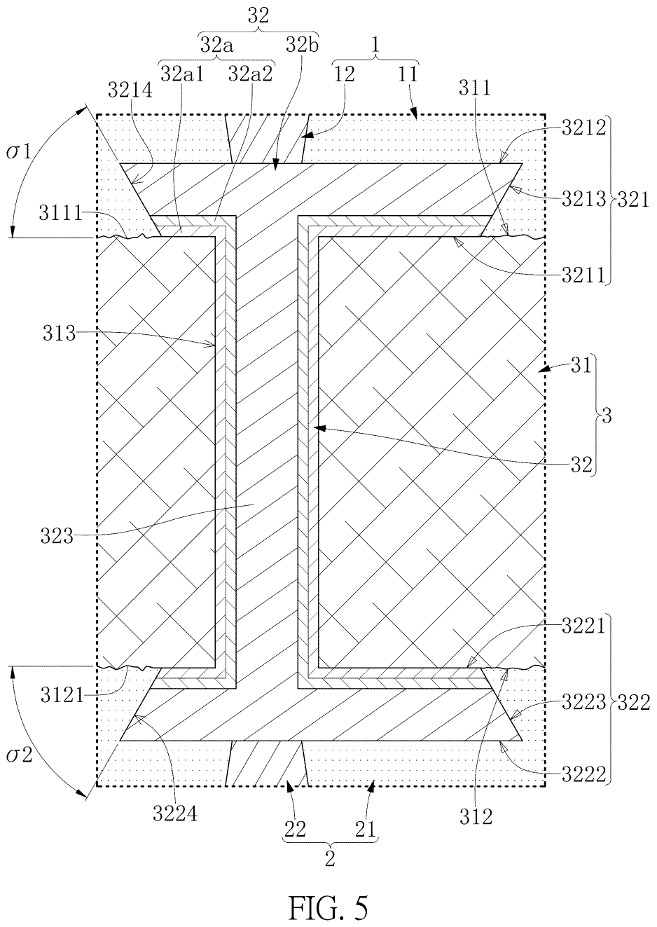

Referring to FIG. 4 to FIG. 6, a third embodiment of the present disclosure, which is similar to the first and second embodiments of the present disclosure, is provided. For the sake of brevity, descriptions of the same components in the first to third embodiments of the present disclosure will be omitted herein, and the following description only discloses different features (e.g., the first connection segment 321 and the second connection segment 322) between the third embodiment and the first and second embodiments.

In the present embodiment, the first connection segment 321 has a first bottom surface 3211 connected to the first surface 311, a first top surface 3212 connected to the first circuit 12, and a first surrounding lateral edge 3213 that is connected in-between the first bottom surface 3211 and the first top surface 3212. The first surrounding lateral edge 3213 and the first surface 311 have a sharp angle σ1 therebetween that can be within a range from 30 degrees to 75 degrees, but the present disclosure is not limited thereto.

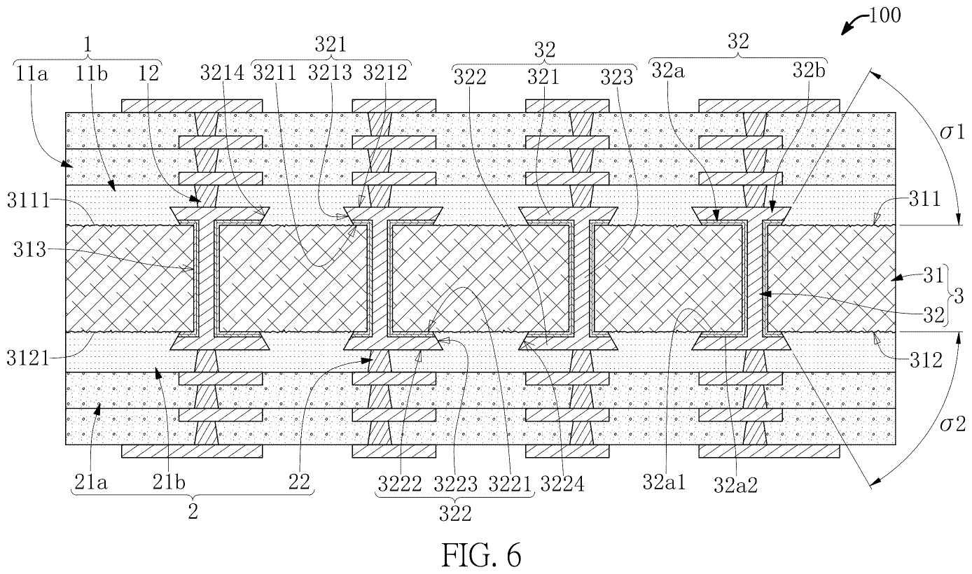

In other words, the first surrounding lateral edge 3213 and the first surface 311 jointly define a first ring-shaped groove 3214 that is filled with the first dielectric layer 11 (as shown in FIG. 4) or one of the first organic dielectric layer 11a and the first inorganic dielectric layer 11b (as shown in FIG. 6), thereby further increasing the bonding strength of the first connection segment 321 and the first stacked layer 1 through the sharp angle σ1.

Moreover, the second connection segment 322 has a second bottom surface 3221 connected to the second surface 312, a second top surface 3222 connected to the second circuit 22, and a second surrounding lateral edge 3223 that is connected in-between the second bottom surface 3221 and the second top surface 3222. The second surrounding lateral edge 3223 and the second surface 312 have a sharp angle σ2 therebetween that can be within a range from 30 degrees to 75 degrees, but the present disclosure is not limited thereto.

In other words, the second surrounding lateral edge 3223 and the second surface 312 jointly define a second ring-shaped groove 3224 that is filled with the second dielectric layer 21 (as shown in FIG. 4) or one of the second organic dielectric layer 21a and the second inorganic dielectric layer 21b (as shown in FIG. 6), thereby further increasing the bonding strength of the second connection segment 322 and the second stacked layer 2 through the sharp angle σ2.

### Fourth Embodiment

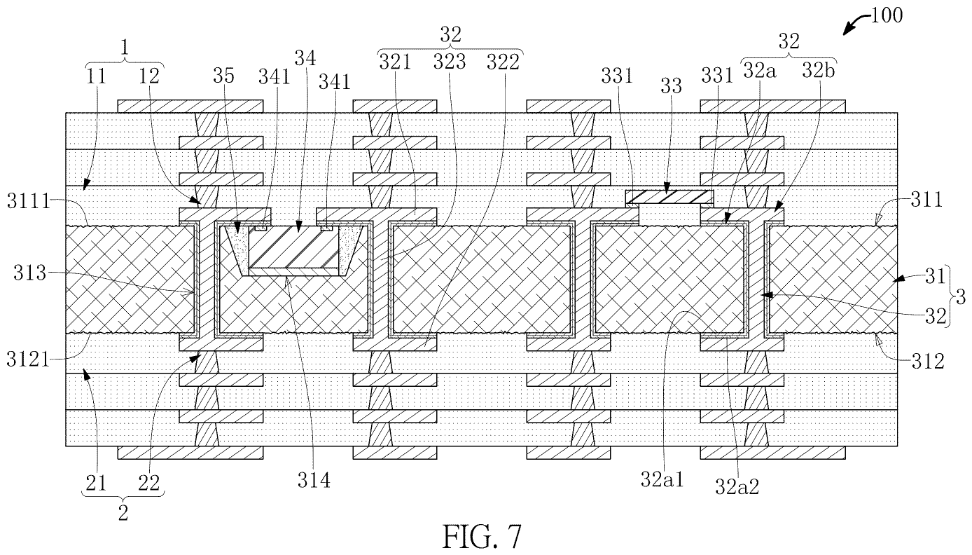

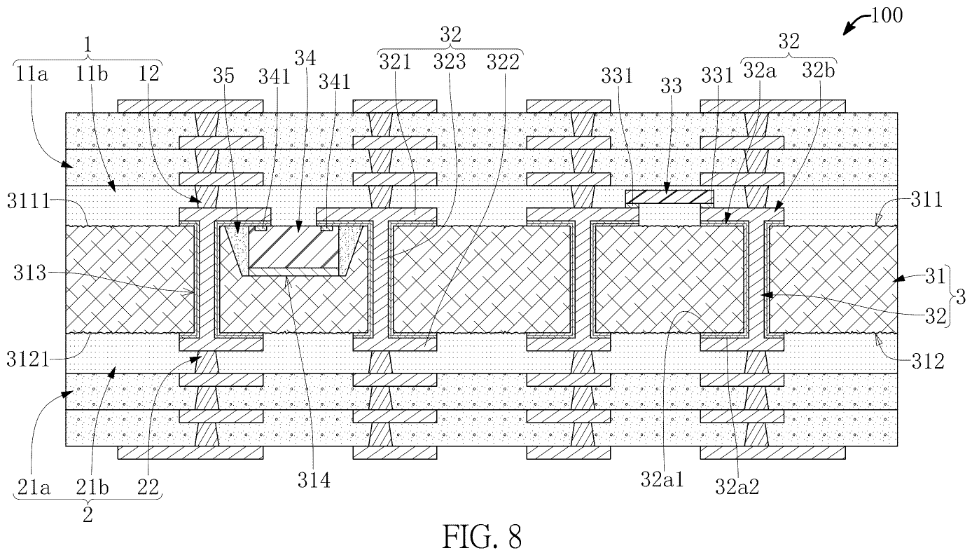

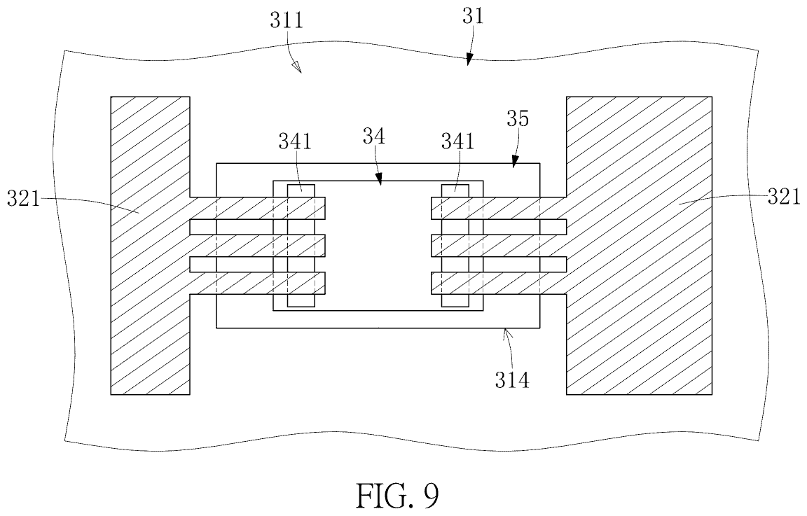

Referring to FIG. 7 to FIG. 9, a fourth embodiment of the present disclosure, which is similar to the first to third embodiments of the present disclosure, is provided. For the sake of brevity, descriptions of the same components in the first to fourth embodiments of the present disclosure will be omitted herein, and the following description only discloses different features (e.g., the ceramic core layer 3) between the fourth embodiment and the first to third embodiments.

In the present embodiment, the ceramic core layer 3 is described by having a plurality of connection circuits 32 and further includes an electronic component 33, an embedded electronic component 34, and an insulator 35. The electronic component 33 is disposed on the first surface 311, two electrodes 331 of the electronic component 33 are respectively connected to the first connection segments 321 of two of the connection circuits 32, and the electronic component 33 is embedded in the first stacked layer 1, but the present disclosure is not limited thereto.

Moreover, the ceramic substrate 31 has an accommodating slot 314 that is recessed in the first surface 311 and that is arranged between the first connection segments 321 of another two of the connection circuits 32. The embedded electronic component 34 is disposed in the accommodating slot 314, and two electrodes 341 of the embedded electronic component 34 are coplanar with the first surface 311. The insulator 35 is filled in the accommodating slot 314 and covers (or encapsulates) the embedded electronic component 34. Furthermore, the first connection segments 321 of the another two of the connection circuits 32 are respectively connected to the two electrodes 341 of the embedded electronic component 34 by extending over the insulator 35.

It should be noted that the electronic component 33 and the embedded electronic component 34 in the present embodiment are arranged corresponding to the first surface 311, but the present disclosure is not limited thereto. For example, in other embodiments of the present disclosure not shown in the drawings, the electronic component 33 and the embedded electronic component 34 are respectively assembled to the first surface 311 and the second surface 312 according to practical requirements; or, the electronic component 33 and the embedded electronic component 34 can be selectively used.

### Beneficial Effects of the Embodiments

In conclusion, the hybrid circuit board of the present disclosure is provided with the ceramic core layer to replace the conventional silicon substrate or the conventional glass substrate, and the first stacked layer and the second stacked layer are ensured to be electrically coupled to each other through the ceramic core layer, thereby effectively increasing the heat dissipation property and the anti-bending property of the hybrid circuit board.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A hybrid circuit board, comprising:
a ceramic core layer including:
a ceramic substrate having a first surface, a second surface being opposite to the first surface, and a thru-hole that penetrates from the first surface to the second surface; and
a connection circuit having an embedded segment filled fully in the thru-hole, a first connection segment, and a second connection segment, wherein the first connection segment and the second connection segment are respectively connected to two opposite ends of the embedded segment, and are respectively formed on the first surface and the second surface;
a first stacked layer formed on the first surface of the ceramic substrate, wherein the first connection segment is embedded in the first stacked layer, and the first stacked layer includes:
a first organic dielectric layer and a first inorganic dielectric layer that are stacked on the first surface; and
a first circuit embedded in the first organic dielectric layer and the first inorganic dielectric layer, wherein one end of the first circuit is connected to the first connection segment, and another end of the first circuit is exposed from one of the first organic dielectric layer and the first inorganic dielectric layer; and
a second stacked layer formed on the second surface of the ceramic substrate, wherein the second connection segment is embedded in the second stacked layer, and the second stacked layer includes:
a second organic dielectric layer and a second inorganic dielectric layer that are stacked on the second surface; and
a second circuit embedded in the second organic dielectric layer and the second inorganic dielectric layer, wherein one end of the second circuit is connected to the second connection segment, another end of the second circuit is exposed from one of the second organic dielectric layer and the second inorganic dielectric layer, and the first circuit and the second circuit are electrically coupled to each other through the connection circuit.

2. The hybrid circuit board according to claim 1, wherein the first surface has a first modification region that is connected to one of the first organic dielectric layer and the first inorganic dielectric layer, and the second surface has a second modification region that is connected to one of the second organic dielectric layer and the second inorganic dielectric layer.

3. The hybrid circuit board according to claim 1, wherein the first connection segment and the second connection segment are respectively formed on the first surface and the second surface in a direct plated copper (DPC) manner.

4. The hybrid circuit board according to claim 1, wherein the first connection segment has a first bottom surface that is connected to the first surface, a first top surface that is connected to the first circuit, and a first surrounding lateral edge that is connected in-between the first bottom surface and the first top surface, and the first surrounding lateral edge and the first surface have a sharp angle therebetween.

5. The hybrid circuit board according to claim 4, wherein the first surrounding lateral edge and the first surface jointly define a first ring-shaped groove that is filled with one of the first organic dielectric layer and the first inorganic dielectric layer.

6. The hybrid circuit board according to claim 4, wherein the sharp angle is within a range from 35 degrees to 75 degrees.

7. The hybrid circuit board according to claim 1, wherein a quantity of the connection circuit in the ceramic core layer is two, and the ceramic core layer includes an electronic component disposed on the first surface, and wherein two electrodes of the electronic component are respectively connected to the first connection segments of the two connection circuits.

8. The hybrid circuit board according to claim 1, wherein a quantity of the connection circuit in the ceramic core layer is two, the ceramic substrate has an accommodating slot that is recessed in the first surface and that is arranged between the first connection segments of the two connection circuits, and the ceramic core layer includes:
an embedded electronic component disposed in the accommodating slot, wherein two electrodes of the embedded electronic component are coplanar with the first surface; and
an insulator filled in the accommodating slot and covering the embedded electronic component, wherein the first connection segments of the two connection circuits are respectively connected to the two electrodes of the embedded electronic component by extending over the insulator.

9. The hybrid circuit board according to claim 1, wherein any one of the first organic dielectric layer and the second organic dielectric layer includes at least one of polyimide (PI), ajinomoto build-up film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, and hybrid polymer-ceramic materials.

10. The hybrid circuit board according to claim 1, wherein any one of the first inorganic dielectric layer and the second inorganic dielectric layer includes at least one of SiO₂, AlON, ZTA, BeO, SiC, Al₂O₃, AlN, Si₃N₄, ZrO_{2,} Quartz, Mica, HfO₂, Ta₂O₃, MgO, TiO₂, and BN.

11. A hybrid circuit board, comprising:
a ceramic core layer including:
a ceramic substrate having a first surface, a second surface being opposite to the first surface, and a thru-hole that penetrates from the first surface to the second surface; and
a connection circuit having an embedded segment filled fully in the thru-hole, a first connection segment, and a second connection segment, wherein the first connection segment and the second connection segment are respectively connected to two opposite ends of the embedded segment, and are respectively formed on the first surface and the second surface;
a first stacked layer including:
a first dielectric layer formed on the first surface; and
a first circuit embedded in the first dielectric layer, wherein one end of the first circuit is connected to the first connection segment, and another end of the first circuit is exposed from the first dielectric layer; and
a second stacked layer including:
a second dielectric layer formed on the second surface; and
a second circuit embedded in the second dielectric layer, wherein one end of the second circuit is connected to the second connection segment, another end of the second circuit is exposed from the second dielectric layer, and the first circuit and the second circuit are electrically coupled to each other through the connection circuit.

12. The hybrid circuit board according to claim 11, wherein the first surface has a first modification region that is connected to the first dielectric layer, and the second surface has a second modification region that is connected to the second dielectric layer.

13. The hybrid circuit board according to claim 11, wherein the first connection segment and the second connection segment are respectively formed on the first surface and the second surface in a direct plated copper (DPC) manner.

14. The hybrid circuit board according to claim 11, wherein the first connection segment has a first bottom surface that is connected to the first surface, a first top surface that is connected to the first circuit, and a first surrounding lateral edge that is connected in-between the first bottom surface and the first top surface, and the first surrounding lateral edge and the first surface have a sharp angle therebetween.

15. The hybrid circuit board according to claim 14, wherein the first surrounding lateral edge and the first surface jointly define a first ring-shaped groove that is filled with the first dielectric layer.

16. The hybrid circuit board according to claim 11, wherein a quantity of the connection circuit in the ceramic core layer is two, and the ceramic core layer includes an electronic component disposed on the first surface, and wherein two electrodes of the electronic component are respectively connected to the first connection segments of the two connection circuits.

17. The hybrid circuit board according to claim 11, wherein a quantity of the connection circuit in the ceramic core layer is two, the ceramic substrate has an accommodating slot that is recessed in the first surface and that is arranged between the first connection segments of the two connection circuits, and the ceramic core layer includes:
an embedded electronic component disposed in the accommodating slot; and
an insulator filled in the accommodating slot and covering the embedded electronic component, wherein the first connection segments of the two connection circuits are respectively connected to two electrodes of the embedded electronic component by extending over the insulator.

18. The hybrid circuit board according to claim 17, wherein the two electrodes of the embedded electronic component are coplanar with the first surface.

19. The hybrid circuit board according to claim 11, wherein at least one of the first dielectric layer and the second dielectric layer is an organic dielectric layer that includes at least one of polyimide (PI), ajinomoto build-up film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, and hybrid polymer-ceramic materials.

20. The hybrid circuit board according to claim 11, wherein at least one of the first dielectric layer and the second dielectric layer is an inorganic dielectric layer that includes at least one of SiO₂, AlON, ZTA, BeO, SiC, Al₂O₃, AlN, Si₃N₄, ZrO_{2,} Quartz, Mica, HfO₂, Ta₂O₃, MgO, TiO₂, and BN.
